(19) United States
(12) Patent Application Publication
(10) Pub. No.: US 2024/0312817 A1
(43) Pub. Date: Sep. 19, 2024

(54) SUBSTRATE CARRIER HAVING INSTALLATION STRUCTURE FOR GAS DIFFUSER

(71) Applicant: GUDENG PRECISION INDUSTRIAL CO, LTD., NNNNew Taipei (TW)

(72) Inventors: Ming-Chien CHIU, New Taipei (TW); Chia-Ho CHUANG, New Taipei (TW); Kuo-Hua LEE, New Taipei (TW); En-Nien SHEN, New Taipei (TW); Jyun-Ming LYU, New Taipei (TW)

(21) Appl. No.: 18/539,477

(22) Filed: Dec. 14, 2023

Related U.S. Application Data
(60) Provisional application No. 63/452,730, filed on Mar. 17, 2023.

(51) Int. Cl. H01L 21/673

(52) U.S. Cl. CPC H01L 21/67386; H01L 21/67393

(57) ABSTRACT

Provided is a substrate carrier including: a shell defining therein a wafer storage space; and at least one installation structure integrally formed with an inner wall of the shell and adapted to hold at least one gas diffuser, allowing the at least one gas diffuser to be disposed outside an operating range of a front end of a robotic arm. Not only is the installation structure of the substrate carrier structurally simplified, but the gas diffuser is also prevented from interfering with the robotic arm.

### CROSS-REFERENCE TO RELATED APPLICATIONS

This divisional application claims priority under 35 U.S.C. § 119(a) on Patent Application No(s). 63/452,730 filed in U.S. on Mar. 17, 2023 the entire contents of which are hereby incorporated by reference.

### BACKGROUND OF THE INVENTION

### Field of the Invention

The present disclosure relates to substrate (wafer) carriers, particularly to a front-opening unified pod (FOUP), and more particularly to a substrate carrier having an installation structure for a gas diffuser.

### Description of the Prior Art

An existing, conventional substrate carrier with a gas diffuser has a container shell. The container shell has therein a plurality of gas diffusers, a plurality of supports and a plurality of fitting-style pipe clips. The fitting-style pipe clips are demountably fitted to the container shell, whereas the gas diffusers are held in the container shell with the pipe clips fitted thereto. The container shell defines therein a wafer storage space. The plurality of gas diffusers are disposed in the wafer storage space and positioned proximate to the rear of the shell to enable a gas to uniformly diffuse into the wafer storage space. However, the conventional fitting-style pipe clips for holding the gas diffusers unfavorably come with a plethora of parts and components to the detriment of quick assembly and cost-effectiveness. Furthermore, the conventional fitting-style pipe clips not only tend to fall off but are also positioned to undesirably interfere with a robotic arm, affecting stored wafers. Last but not least, each conventional fitting-style pipe clip has a large contact area with the corresponding gas diffuser, generating a lot of dust particles from friction therebetween.

### SUMMARY OF THE INVENTION

In view of the aforesaid drawbacks of the prior art, the disclosure is aimed at providing an integrated installation structure for securing at least one gas diffuser to a shell from inside to simplify an assembly process with a view to speeding up the assembly process and cutting cost. The disclosure is further aimed at reducing the contact area between the clamping portion of the integrated installation structure and the gas diffuser and thereby reducing dust particles which might otherwise be generated from friction therebetween.

It is an objective of the disclosure to provide a substrate carrier, comprising: a shell defining therein a wafer storage space; and at least one installation structure integrally formed with an inner wall of the shell and adapted to hold at least one gas diffuser, allowing the at least one gas diffuser to be disposed outside an operating range of a front end of a robotic arm.

In a specific embodiment, the installation structure comprises a first clamping arm, a second clamping arm and an abutting portion, the first and second clamping arms clamping the gas diffuser, and the abutting portion abutting against the gas diffuser.

In a specific embodiment, the first clamping arm or the second clamping arm is resilient.

In a specific embodiment, the first clamping arm or the second clamping arm further comprises a supporting portion extending from the inner wall and a clamping portion extending from the supporting portion, the supporting portion being of a greater thickness than the clamping portion.

In a specific embodiment, the first clamping arm and the second clamping arm define an upper opening and a lower opening, with the upper opening being smaller than the lower opening.

In a specific embodiment, the upper opening has an upper inner diameter, and the lower opening has a lower inner diameter, with the upper inner diameter being less than the lower inner diameter.

In a specific embodiment, a diameter of the gas diffuser is less than the lower inner diameter.

In a specific embodiment, the gas diffuser has a smaller contact area with the first clamping arm and the second clamping arm than with the abutting portion.

In a specific embodiment, a cross section of the gas diffuser is round, elliptical, or of any other shape.

In a specific embodiment, the first clamping arm, the second clamping arm, the abutting portion and the gas diffuser define at least one water-discharge vent.

Another objective of the disclosure is to provide a substrate carrier, comprising: a shell defining therein a wafer storage space; and at least one installation structure comprising a first clamping arm and a second clamping arm, the first and second clamping arms extending from an inner wall of the shell in an integrally-formed manner and adapted to clamp at least one gas diffuser.

In a specific embodiment, the installation structure further comprises an abutting portion disposed between the first clamping arm and the second clamping arm.

In a specific embodiment, the gas diffuser has a smaller contact area with the first clamping arm and the second clamping arm than with the abutting portion.

In a specific embodiment, the first clamping arm, the second clamping arm and the gas diffuser define at least one water-discharge vent.

In a specific embodiment, the upper opening has an upper inner diameter, and the lower opening has a lower inner diameter, with the upper inner diameter being less than the lower inner diameter.

In a specific embodiment, a diameter of the gas diffuser is less than the lower inner diameter.

In a specific embodiment, upper ends of the first and second clamping arms are in direct contact with the at least one gas diffuser, and a gap is defined between the at least one gas diffuser and each of lower ends of the first and second clamping arms.

In a specific embodiment, the first clamping arm or the second clamping arm further comprises a supporting portion extending from the inner wall and a clamping portion extending from the supporting portion, the supporting portion having greater mechanical strength than the clamping portion.

In a specific embodiment, the clamping portion is resilient, and the supporting portion is of a greater thickness than the clamping portion.

In a specific embodiment, the installation structure is disposed outside an operating range of a front end of a robotic arm.

### BRIEF DESCRIPTION OF THE DRAWINGS

FIG. 1 is a schematic front view of a substrate carrier having an installation structure for a gas diffuser according to the first embodiment of the disclosure.

FIG. 2 is a top view of the cross section of the substrate carrier taken along line A-A of FIG. 1 according to the first embodiment of the disclosure.

FIG. 3A is an enlarged view of the installation structure of the substrate carrier according to the first embodiment of the disclosure.

FIG. 3B is a cutaway view of the installation structure of the substrate carrier according to the first embodiment of the disclosure.

FIG. 3C is a front view of the installation structure of the substrate carrier according to the first embodiment of the disclosure.

FIG. 3D is a front view of the installation structure clamping the gas diffuser according to the first embodiment of the disclosure.

FIG. 4 is an enlarged top view of an installation structure of a substrate carrier according to a second embodiment of the disclosure.

### DETAILED DESCRIPTION OF THE EMBODIMENTS

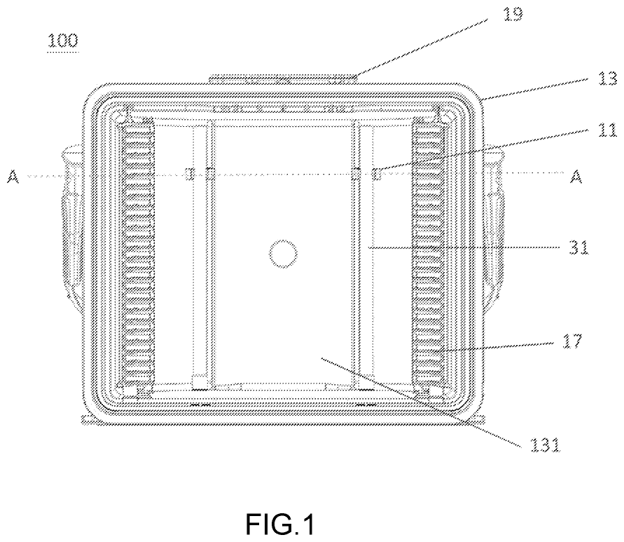

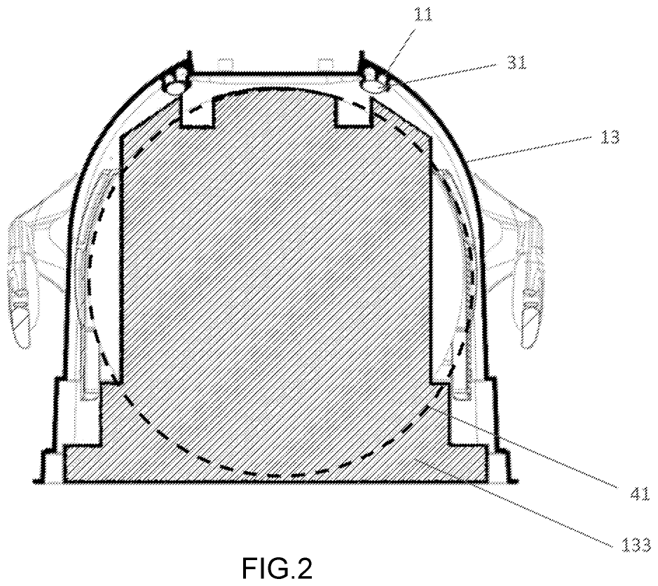

Referring to FIG. 1, schematically shown is a substrate carrier 100 having an installation structure 11 for a gas diffuser according to the first embodiment of the disclosure. The substrate carrier 100 comprises at least one installation structure 11 and a shell 13. The shell 13 has an inner wall 132 and defines a wafer storage space 131. The inner wall 132 of the shell 13 is located at the rear of the shell 13 and positioned distal to an opening at the front of the shell 13. The installation structure 11 is integrally formed with the inner wall 132 of the shell 13 and adapted to hold at least one gas diffuser 31. The substrate carrier 100 further comprises a wafer rack 17 and a grip 19. The wafer rack 17 is disposed in the wafer storage space 131 and adapted to carry a wafer 41 shown in FIG. 2.

Referring to FIG. 2, there is shown a cross-sectional view taken along line A-A of FIG. 1. As shown in the diagram, the installation structure 11 extends from the inner wall 132 of the shell 13 in an integrally-formed manner and is disposed outside an operating range 133 of the front end of a robotic arm. Thus, when the gas diffuser 31 is installed on the substrate carrier 100, not only is the gas diffuser 31 located outside the operating range 133 of the front end of the robotic arm, but the gas diffuser 31 is also not in contact with the stored wafer 41, reducing the risk of collisions between the gas diffuser 31 and the robotic arm.

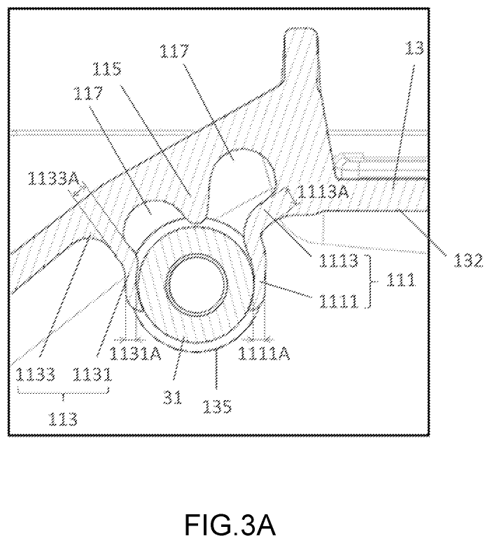

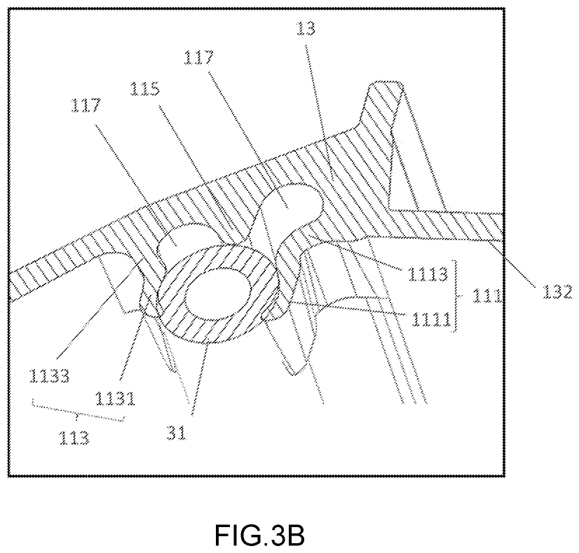

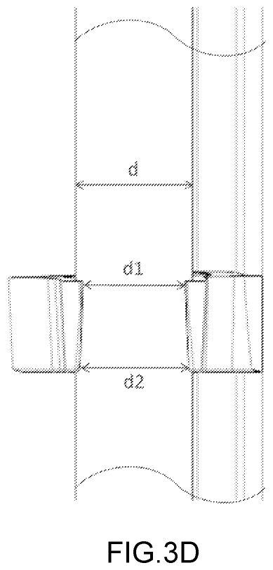

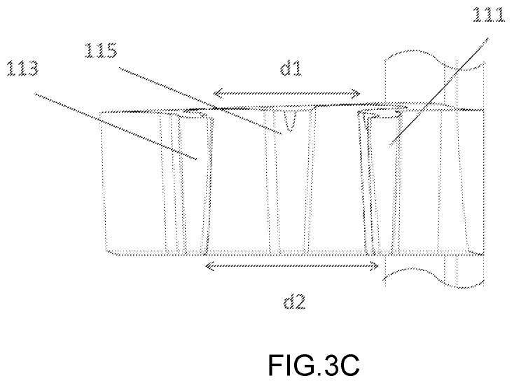

Referring to FIGS. 3A and 3B, the installation structure 11 comprises a first clamping arm 111 and a second clamping arm 113 which extend from the inner wall 132 of the shell 13 in an integrally-formed manner. In this embodiment, both the installation structure 11 and the shell 13 are made of the same material. In another possible embodiment, the shell 13 and a portion of the installation structure 11 are made of the same material, whereas the shell 13 and the other portion of the installation structure 11 are made of different materials. The installation structure 11 holds or clamps the gas diffuser 31 through the first clamping arm 111 and the second clamping arm 113. The installation structure 11 further comprises an abutting portion 115 formed between the first clamping arm 111 and the second clamping arm 113 and adapted to abut against the gas diffuser 31 to enhance the stability of the gas diffuser 31. The gas diffuser 31 has a smaller contact area with the first clamping arm 111 and the second clamping arm 113 than with the abutting portion 115 to minimize the contact area between the installation structure 11 and the gas diffuser 31. Preferably, the contact surface of the abutting portion 115 is convex to avoid scratching the gas diffuser 31.

In an embodiment of the disclosure, the first clamping arm 111 further comprises a first clamping portion 1111 and a first supporting portion 1113, whereas the second clamping arm 113 further comprises a second clamping portion 1131 and a second supporting portion 1133. The first supporting portion 1113 and the second supporting portion 1133 each extend from the inner wall 132 and are each configured to have appropriate thickness for providing clamping strength and stability. The first clamping portion 1111 extends from the first supporting portion 1113. The second clamping portion 1131 extends from the second supporting portion 1133. Each of free ends of the first and second clamping portions 1111, 1131 defines an opening for admitting the gas diffuser 31 into a receiving space defined between the first clamping arm 111 and the second clamping arm 113, allowing the first clamping portion 1111 and the second clamping portion 1131 to come into contact with the gas diffuser 31. The first clamping arm 111 and the second clamping arm 113 are not only resilient but also appropriately deformable in accordance with the outline of the gas diffuser 31 and any acting force to facilitate the installation of the gas diffuser 31. Both the first clamping arm 111 and the second clamping arm 113 can absorb and alleviate the vibration arising from the gas diffuser 31 in the course of inflation while the substrate carrier 100 is being moved or used in a manufacturing fab.

The first supporting portion 1113 has greater mechanical strength than the first clamping portion 1111, and the second supporting portion 1133 has greater mechanical strength than the second clamping portion 1131, precluding deformation and fractures. Therefore, the first supporting portion 1113 and the second supporting portion 1133 demonstrate greater capability to resist deformation or bending than the first clamping portion 1111 and the second clamping portion 1131. In the embodiment illustrated by FIG. 3A, a section thickness 1113A of the first supporting portion 1113 is greater than a section thickness 1111A of the first clamping portion 1111, and a section thickness 1133A of the second supporting portion 1133 is greater than a section thickness 1131A of the second clamping portion 1131.

When the gas diffuser 31 is installed on the substrate carrier 100, one end of the gas diffuser 31 is positioned at a coupling portion 135 at the bottom of the substrate carrier 100. For instance, the coupling portion 135 is not only a sleeve disposed at the bottom of the shell 13 and adapted to receive the bottom of the gas diffuser 31 but also has a means of hermetic sealing for achieving airtightness between the gas diffuser 31 and the coupling portion 135. Alternatively, the coupling portion 135 is a connection unit disposed at the bottom of the shell 13, and the bottom of the gas diffuser 31 is fitted to the connection unit. The tubular body of the gas diffuser 31 is held by the first clamping arm 111 and the second clamping arm 113. The opening between the first clamping portion 1111 and the second clamping portion 1131 is controlled by the appropriate deformation of the first clamping portion 1111 and the second clamping portion 1131 to allow the tubular body of the gas diffuser 31 to be inserted into the receiving space between the first clamping arm 111 and the second clamping arm 113 such that the fracture of the installation structure 11 is prevented in the course of assembly because of the mechanical strength provided by the first supporting portion 1113 or second supporting portion 1133, each of which has relatively greater mechanical strength.

Furthermore, at least one water-discharge vent 117 is defined between the first clamping arm 111 and the second clamping arm 113 of the installation structure 11 to enable drainage by allowing rinsing liquid to drain away from behind the shell 13 when the gas diffuser 31 is mounted on the shell 13. In an embodiment of the disclosure, when the gas diffuser 31 is mounted on the shell 13, a water-discharge vent 117 is defined between the first clamping arm 111 and the abutting portion 115, and another water-discharge vent 117 is defined between the second clamping arm 113 and the abutting portion 115.

Referring to FIGS. 3C and 3D, the first clamping arm 111 and the second clamping arm 113 define the openings penetrable by the gas diffuser 31, an upper opening and a lower opening. The upper opening is slightly smaller than the lower opening. As shown in FIG. 3C, upper ends of the first and second clamping arms 111, 113 are thick, but lower ends of the first and second clamping arms 111, 113 are thin. Thus, a portion of the first and second clamping arms 111, 113 is in direct contact with the gas diffuser 31, and a tiny gap is formed between the other portion of the first and second clamping arms 111, 113 and the gas diffuser 31. Since part of the first and second clamping arms 111, 113 is not in contact with the surface of the gas diffuser 31, the contact area between the installation structure 11 and the gas diffuser 31 is minimized, reducing dust particles which might otherwise be generated. Specifically speaking, the upper ends of the first and second clamping arms 111, 113 are in direct contact with the gas diffuser 31, but the lower ends of the first and second clamping arms 111, 113 are not in contact with the gas diffuser 31. Since the lower ends of the first and second clamping arms 111, 113 are not in contact with the gas diffuser 31, dust particles generated from friction are prevented from accumulating between the gas diffuser 31 and each of the first clamping arm 111 and the second clamping arm 113.

Furthermore, when the installation structure 11 is not installed on the gas diffuser 31, the upper opening has an upper inner diameter d1, and the lower opening has a lower inner diameter d2. The inner diameters of the first clamping arm 111 and the second clamping arm 113 gradually increase from the upper inner diameter d1 to the lower inner diameter d2. The upper inner diameter d1 is less than the lower inner diameter d2 and is slightly less than the gas diffuser diameter d to ensure that the installation structure 11 can firmly hold the gas diffuser 31. The lower inner diameter d2 is greater than the gas diffuser diameter d such that a gap is defined between the surface of the gas diffuser 31 and lower surfaces of the first and second clamping arms 111, 113 to reduce the dust particles which might otherwise be generated. In addition, another means can be employed to allow a portion of the first and second clamping arms 111, 113 to be in contact with the gas diffuser 31. For instance, the first clamping arm 111 and the second clamping arm 113 can have variable thickness. Alternatively, the first clamping arm 111 and the second clamping arm 113 have irregular surfaces.

The abutting portion 115 is in direct contact with the gas diffuser 31 in whole or in part. Alternatively, the abutting portion 115 is fully in contact with the gas diffuser 31 to ensure the stability of holding the gas diffuser 31. Alternatively, the abutting portion 115 is partially in contact with the gas diffuser 31; for example, only the upper end of the abutting portion 115 is in direct contact with the gas diffuser 31, and a gap is defined between the lower end of the abutting portion 115 and the surface of the gas diffuser 31, so as to minimize the contact area between the abutting portion 115 and the gas diffuser 31 and thereby reduce the dust particles which might otherwise be generated.

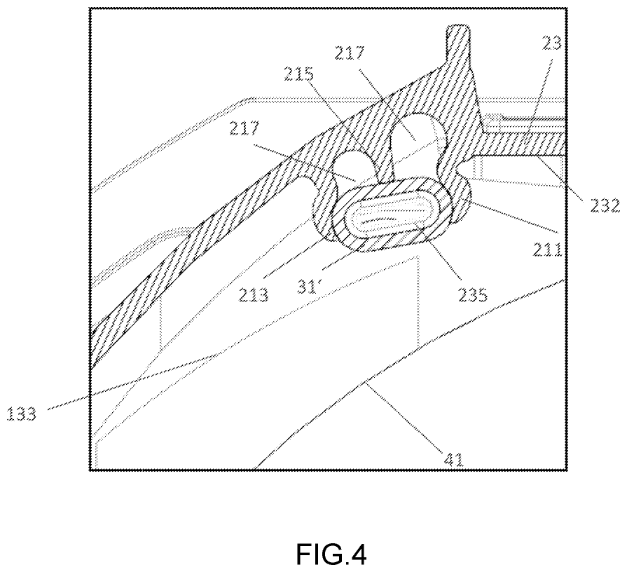

Referring to FIG. 4, there is shown a cross-sectional view of an installation structure according to a second embodiment of the disclosure. The first and second embodiments of the installation structure are similar in structure and features for the purpose of assembly or replacement. However, unlike the first embodiment, the second embodiment features a gas diffuser 31′ with an elliptical cross section.

Specifically speaking, in the second embodiment of the disclosure, the substrate carrier 100 comprises the installation structure 11 formed on an inner wall 232 of a shell 23 and further comprises a first clamping arm 211 and a second clamping arm 213 for holding or clamping the gas diffuser 31′ with an elliptical cross section. Specifically speaking, the first clamping arm 211 and the second clamping arm 213 are configured to clamp the gas diffuser 31′ with an elliptical cross section from two opposing sides of the corresponding axis, respectively. In another possible embodiment, the first clamping arm 211 and the second clamping arm 213 are configured to clamp the gas diffuser 31 with at least one cross-sectional shape or of one shape but in different orientations. The installation structure further comprises the abutting portion 215 for abutting against the gas diffuser 31′.

When the gas diffuser 31′ is mounted on the substrate carrier 100, the gas diffuser 31′ is positioned at a coupling portion 235 at the bottom of the substrate carrier 100, held or clamped by the first clamping arm 211 and the second clamping arm 213, and abutted against by the abutting portion 215, whereas a water-discharge vent 217 is defined between the first clamping arm 211 and the abutting portion 215 and between the second clamping arm 213 and the abutting portion 215 to enable drainage by allowing rinsing liquid to drain away.

The installation structure 11 extends from the inner wall 232 of the shell 23. Thus, when the gas diffuser 31′ is installed on the substrate carrier 100, the operating range 133 of the front end of the robotic arm is not in contact with the stored wafer 41, reducing the risk of collisions between the gas diffuser 31′ and the robotic arm.

In the first and second embodiments of the disclosure, the installation structure is integrally formed with the container shell. During the manufacturing process, the installation structure suitable for clamping gas diffusers of different shapes is manufactured with the same sleeve mold having a replaceable mold insert and an angle lifter structure; for example, the installation structure thus manufactured can clamp a gas diffuser whose cross section is round, elliptical, or of any other shape to reduce the manufacturing cost of the shell and increase the ease of manufacturing the shell.

What is claimed is:

1. A substrate carrier, comprising:
a shell defining therein a wafer storage space; and
at least one installation structure integrally formed with an inner wall of the shell and adapted to hold at least one gas diffuser, allowing the at least one gas diffuser to be disposed outside an operating range of a front end of a robotic arm.

2. The substrate carrier of claim 1, wherein the installation structure comprises a first clamping arm, a second clamping arm and an abutting portion, the first and second clamping arms clamping the gas diffuser, and the abutting portion abutting against the gas diffuser.

3. The substrate carrier of claim 2, wherein the first clamping arm or the second clamping arm is resilient.

4. The substrate carrier of claim 2, wherein the first clamping arm or the second clamping arm further comprises a supporting portion extending from the inner wall and a clamping portion extending from the supporting portion, the supporting portion being of a greater thickness than the clamping portion.

5. The substrate carrier of claim 2, wherein the first clamping arm and the second clamping arm define an upper opening and a lower opening, with the upper opening being smaller than the lower opening.

6. The substrate carrier of claim 5, wherein the upper opening has an upper inner diameter, and the lower opening has a lower inner diameter, with the upper inner diameter being less than the lower inner diameter.

7. The substrate carrier of claim 6, wherein a diameter of the gas diffuser is less than the lower inner diameter.

8. The substrate carrier of claim 2, wherein the gas diffuser has a smaller contact area with the first clamping arm and the second clamping arm than with the abutting portion.

9. The substrate carrier of claim 1, wherein a cross section of the gas diffuser is round, elliptical, or of any other shape.

10. The substrate carrier of claim 1, wherein the first clamping arm, the second clamping arm, the abutting portion and the gas diffuser define at least one water-discharge vent.

11. A substrate carrier, comprising:
a shell defining therein a wafer storage space; and
at least one installation structure comprising a first clamping arm and a second clamping arm, the first and second clamping arms extending from an inner wall of the shell in an integrally-formed manner and adapted to clamp at least one gas diffuser.

12. The substrate carrier of claim 11, wherein the installation structure further comprises an abutting portion disposed between the first clamping arm and the second clamping arm.

13. The substrate carrier of claim 12, wherein the gas diffuser has a smaller contact area with the first clamping arm and the second clamping arm than with the abutting portion.

14. The substrate carrier of claim 11, wherein the first clamping arm, the second clamping arm and the gas diffuser define at least one water-discharge vent.

15. The substrate carrier of claim 11, wherein the first clamping arm and second clamping arm define an upper inner diameter is less than a lower inner diameter.

16. The substrate carrier of claim 15, wherein a diameter of the gas diffuser is less than the lower inner diameter.

17. The substrate carrier of claim 11, wherein upper ends of the first and second clamping arms are in direct contact with the at least one gas diffuser, and a gap is defined between the at least one gas diffuser and each of lower ends of the first and second clamping arms.

18. The substrate carrier of claim 11, wherein the first clamping arm or the second clamping arm further comprises a supporting portion extending from the inner wall and a clamping portion extending from the supporting portion, the supporting portion having greater mechanical strength than the clamping portion.

19. The substrate carrier of claim 18, wherein the clamping portion is resilient, and the supporting portion is of a greater thickness than the clamping portion.

20. The substrate carrier of claim 11, wherein the installation structure is disposed outside an operating range of a front end of a robotic arm.
